(19) United States
(12) Patent Application Publication
(10) Pub. No.: US 2023/0320175 A1
(43) Pub. Date: Oct. 5, 2023

(54) DISPLAY APPARATUS AND METHOD OF MANUFACTURING THE SAME

(71) Applicant: SAMSUNG DISPLAY CO., LTD., Yongin-si (KR)

(72) Inventors: Ilhun SEO, Yongin-si (KR); Kyungwon PARK, Yongin-si (KR); Junho PARK, Yongin-si (KR); Woosik JUN, Yongin-si (KR)

(21) Appl. No.: 18/130,507

(22) Filed: Apr. 4, 2023

(30) Foreign Application Priority Data
Apr. 4, 2022 (KR) 10-2022-0041909

(51) Int. Cl. H10K 59/80; H10K 59/38; H10K 59/122; H10K 59/131; H10K 59/12

(52) U.S. Cl. CPC H10K 59/8722; H10K 59/38; H10K 59/122; H10K 59/131; H10K 59/873; H10K 59/879; H10K 59/1201

(57) ABSTRACT

A display apparatus and a method of manufacturing a display apparatus are disclosed. The display apparatus includes a first substrate including a display area and a non-display area outside the display area, a pixel electrode located on the display area of the first substrate, a second substrate located over the first substrate with the pixel electrode therebetween, a sealing member located between the first substrate and the second substrate to attach the first substrate and the second substrate to each other, a metal pattern located on the first substrate to be adjacent to the sealing member at the inner side of the sealing member, and a connection wiring connected to the metal pattern and extending to an edge of the first substrate.

This application claims priority to Korean Patent Application No. 10-2022-0041909, filed on Apr. 4, 2022, the content of which in its entirety is herein incorporated by reference.

### BACKGROUND

### 1. Field

One or more embodiments relate to a display apparatus and a method of manufacturing the same, and more particularly, to a display apparatus for displaying a high-quality image and a method of manufacturing the display apparatus.

### 2. Description of the Related Art

A display apparatus includes a plurality of pixels. For a full-color display apparatus, the plurality of pixels may emit light of different colors. To this end, at least some pixels of the display apparatus include a color conversion unit. Accordingly, light of a first wavelength band generated by a light-emitting unit of some pixels is converted into light of a second wavelength band while passing through a corresponding color conversion unit and is extracted to the outside.

### SUMMARY

However, a display apparatus in the related art has a problem in that moisture penetrates into some layers of the display apparatus during a manufacturing process, thereby reducing a lifespan of the display apparatus.

One or more embodiments include a display apparatus for reducing the risk of defects in a manufacturing process and a method of manufacturing the display apparatus. However, the embodiments are examples, and do not limit the scope of the disclosure.

Additional aspects will be set forth in part in the description which follows and, in part, will be apparent from the description, or may be learned by practice of the presented embodiments.

According to one or more embodiments, a display apparatus includes: a first substrate including a display area and a non-display area outside the display area, a pixel electrode located on the display area of the first substrate, a second substrate located over the first substrate with the pixel electrode therebetween, a sealing member between the first substrate and the second substrate to attach the first substrate and the second substrate to each other, a metal pattern arranged on the first substrate to be adjacent to the sealing member at an inner side of the sealing member, and a connection wiring connected to the metal pattern and extending to an edge of the first substrate.

The metal pattern may contact an inner surface of the sealing member.

The display apparatus may further include a gate wiring located on the non-display area of the first substrate, where the gate wiring is located at the inner side of the sealing member in a plan view.

The metal pattern may overlap the gate wiring in the plan view.

The gate wiring may include a first gate wiring and a second gate wiring, which are spaced apart from each other with the metal pattern therebetween, and a bridge line overlapping the metal pattern, in the plan view, an insulating layer is located between a layer where the bridge line is located, and a layer where the first gate wiring and the second gate wiring are located, and the first gate wiring and the second gate wiring are electrically connected through the bridge line.

The connection wiring may include the same material as a material of the first gate wiring and the second gate wiring.

The display apparatus may further include a guard ring located on the non-display area, and arranged on the first substrate to overlap the sealing member in the plan view, where the guard ring includes the same material as a material of the bridge line.

The display apparatus may further include a dam portion arranged on the non-display area of the first substrate to surround at least a part of the display area, where the metal pattern is located between the sealing member and the dam portion in a plan view.

The metal pattern may include silver (Ag).

The metal pattern and the pixel electrode may include the same material.

The metal pattern may be located at a corner of the first substrate.

The metal pattern may be provided in plural so that a plurality of metal patterns are comprised and the corner of the first substrate may be provided in plural so that a plurality of corners are comprised, where the plurality of metal patterns may be located at the corners of the first substrate, respectively.

The display apparatus may further include a first organic layer located at the inner side of the sealing member, and covering a top surface of the metal pattern.

The display apparatus may further include a pixel-defining film located on the pixel electrode, and covering an edge of the pixel electrode and exposing a central portion of the pixel electrode, where the first organic layer includes the same material as a material of the pixel-defining film.

The display apparatus may further include a second organic layer located between the metal pattern and the first substrate.

The display apparatus may further include a color filter layer located on a bottom surface of the second substrate facing the first substrate, and including at least two color filters, where the at least two color filters may overlap each other on the non-display area in a plan view.

The display apparatus may further include: a refractive layer located on a bottom surface of the color filter layer facing the first substrate, and having a refractive index lower than a refractive index of the color filter layer, a capping layer located on a bottom surface of the refractive layer facing the first substrate, and having a refractive index higher than the refractive index of the refractive layer, and an attachment portion located between the capping layer and the sealing member.

The attachment portion may have a closed loop shape overlapping the sealing member in the plan view.

The connection wiring may be a part of a wiring, which connects the metal pattern to a monitoring pad located outside the edge of the first substrate.

According to one or more embodiments, a method of manufacturing a display apparatus includes: forming a first substrate including a display area and a non-display area surrounding the display area, forming a metal pattern on the non-display area of the first substrate, and forming a connection wiring, which electrically connects the metal pattern to a monitoring pad located outside the non-display area, attaching a second substrate to the first substrate by using a sealing member, and measuring a change in electrical characteristics of the metal pattern by using the monitoring pad.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating a display apparatus, according to an embodiment;

FIG. 2 is a cross-sectional view schematically illustrating a display apparatus, according to an embodiment;

FIGS. 3A and 3B are equivalent circuit diagrams each illustrating a pixel included in a display apparatus, according to embodiments;

FIG. 4 is a cross-sectional view taken along line A-A′ of the display apparatus shown in FIG. 1;

FIGS. 5A and 5B are plan views each illustrating a portion of a base substrate, according to embodiments;

FIG. 6 is a cross-sectional view taken along line C-C′ of the base substrate shown in FIG. 5A;

FIG. 7 is a cross-sectional view taken along line D-D′ of the base substrate shown in FIG. 5A; and

FIG. 8 is a cross-sectional view illustrating a portion of a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

While such terms as “first,” “second,” etc., may be used to describe various components, such components are not be limited to the above terms. The above terms are used only to distinguish one component from another.

The singular forms “a,” “an,” and “the” as used herein are intended to include the plural forms as well unless the context clearly indicates differently.

In the following embodiments, it is to be understood that the terms “including,” “having,” and “comprising” are intended to indicate the existence of features or components described in the specification, and are not intended to preclude the possibility that one or more other features or components may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

In the specification, it will be understood that when a layer, an area, or a component is referred to as being “connected” to another layer, area, or component, it may be “directly connected” to the other layer, area, or component and/or may be “indirectly connected” to the other layer, area, or component with other layers, areas, or components interposed therebetween. For example, when a layer, an area, or a component is referred to as being “electrically connected,” it may be directly electrically connected, and/or may be indirectly electrically connected with intervening layers, areas, or components therebetween.

“A and/or B” is used herein to select only A, select only B, or select both A and B. “At least one of A and B” is used to select only A, select only B, or select both A and B.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be different from the described order. For example, two consecutively described processes may be performed substantially at the same time or may be performed in an order opposite to the described order.

Sizes of components in the drawings may be exaggerated or contracted for convenience of explanation. For example, because sizes and thicknesses of elements in the drawings are arbitrarily illustrated for convenience of explanation, the disclosure is not limited thereto.

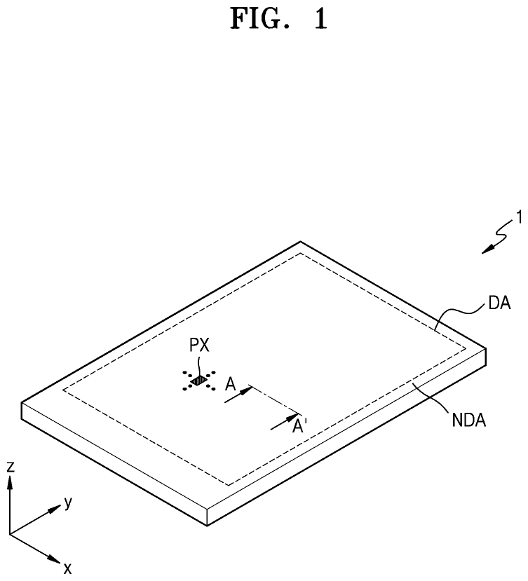

FIG. 1 is a perspective view schematically illustrating a display apparatus 1, according to an embodiment.

Referring to FIG. 1, a display apparatus 1 may include a display area DA where an image is formed and a non-display area NDA where an image is not formed. The display apparatus 1 may provide an image to the outside by using light emitted from the display area DA.

Although the display area DA of the display apparatus 1 has a quadrangular shape in FIG. 1, in another embodiment, the display area DA may have a circular shape, an elliptical shape, or a polygonal shape such as a triangular shape or a pentagonal shape. Also, although the display apparatus 1 of FIG. 1 is a flat panel display apparatus, the display apparatus 1 may be implemented as any of various apparatuses such as a flexible, foldable, or rollable display apparatus. For convenience of explanation, an embodiment in which the display apparatus 1 has the quadrangular shape, short sides extend in x-axis direction and long sides extend in y-axis direction will be described.

In an embodiment, the display apparatus 1 may be an organic light-emitting display apparatus. In another embodiment, the display apparatus 1 may be an inorganic light-emitting display apparatus or a quantum-dot light-emitting display apparatus. For example, an emission layer of a display element included in the display apparatus 1 may include an organic material, may include an inorganic material, may include quantum dots, may include an organic material and quantum dots, may include an inorganic material and quantum dots, or may include an organic material, an inorganic material, and quantum dots. For convenience of explanation, the following will be described assuming that the display apparatus 1 is an organic light-emitting display apparatus.

A plurality of pixels PX may be located in the display area DA. The display area DA may display a certain image by using light emitted by the pixels PX. In the specification, the pixel PX may be defined as an emission area where one of red light, green light, and blue light is emitted. In the specification, each pixel PX refers to one of sub-pixels that emit light of different colors, and may be any one of, for example, a red sub-pixel, a green sub-pixel, and a blue sub-pixel.

The non-display area NDA is an area where the pixel PX is not located, and a power supply wiring or the like for driving the pixel PX may be located in the non-display area NDA. Also, a printed circuit board including a driving circuit unit or a terminal unit to which a driver integrated circuit (“IC”) is connected may be located in the non-display area NDA. The driving circuit unit may be located in the non-display area NDA.

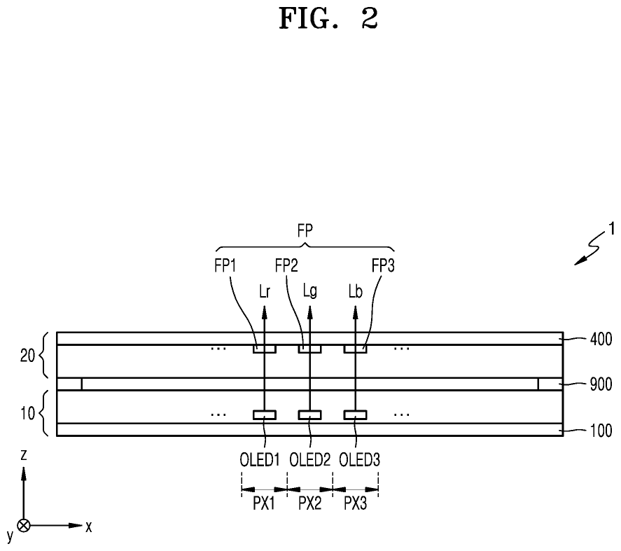

FIG. 2 is a cross-sectional view schematically illustrating a display apparatus 1, according to an embodiment.

Referring to FIG. 2, the display apparatus 1 may include a first pixel PX1, a second pixel PX2, and a third pixel PX3. The first pixel PX1, the second pixel PX2, and the third pixel PX3 may be pixels that emit light of different colors. For example, the first pixel PX1 may emit red light Lr, the second pixel PX2 may emit green light Lg, and the third pixel PX3 may emit blue light Lb. In an embodiment, the display apparatus 1 may include a display panel 10 and a color conversion panel 20. The display panel 10 may include a first substrate 100 and a display element. The display element may be, for example, an organic light-emitting diode. In an embodiment, each of the first pixel PX1, the second pixel PX2, and the third pixel PX3 may include an organic light-emitting diode. For example, the first pixel PX1 may include a first organic light-emitting diode OLED1. The second pixel PX2 may include a second organic light-emitting diode OLED2. The third pixel PX3 may include a third organic light-emitting diode OLED3.

In an embodiment, the first organic light-emitting diode OLED1, the second organic light-emitting diode OLED2, and the third organic light-emitting diode OLED3 may emit blue light. In the embodiment shown in FIG. 2, the first organic light-emitting diode OLED1, the second organic light-emitting diode OLED2, and the third organic light-emitting diode OLED3 may emit the red light Lr, the green light Lg, and the blue light Lb, respectively.

The color conversion panel 20 may include a second substrate 400 and a filter unit FP. In an embodiment, the filter unit FP may include a first filter unit FP1, a second filter unit FP2, and a third filter unit FP3. Light emitted by the first organic light-emitting diode OLED1 may pass through the first filter unit FP1 and may be emitted as the red light Lr. Light emitted by the second organic light-emitting diode OLED2 may pass through the second filter unit FP2 and may be emitted as the green light Lg. Light emitted by the third organic light-emitting diode OLED3 may pass through the third filter unit FP3 and may be emitted as the blue light Lb.

In an embodiment, the filter unit FP may include a functional layer and a color filter layer. In an embodiment, the functional layer may include a first quantum dot layer, a second quantum dot layer, and a transmissive layer. In an embodiment, the color filter layer may include a first color filter, a second color filter, and a third color filter. The first filter unit FP1 may include the first quantum dot layer and the first color filter. The second filter unit FP2 may include the second quantum dot layer and the second color filter. The third filter unit FP3 may include the transmissive layer and the third color filter.

The filter unit FP may be located directly on the second substrate 400. In this case, when the filter unit FP is located ‘directly on the second substrate 400,’ it may mean that the color conversion panel 20 is manufactured by directly forming the first color filter, the second color filter, and the third color filter on the second substrate 400. Next, the color conversion panel 20 may be adhered to the display panel 10 so that the first filter unit FP1, the second filter unit FP2, and the third filter unit FP3 face the first organic light-emitting diode OLED1, the second organic light-emitting diode OLED2, and the third organic light-emitting diode OLED3, respectively.

The display panel 10 and the color conversion panel 20 may be connected to each other through a sealing member 900. In this case, the sealing member 900 may surround the display area DA of the display panel 10. For example, the sealing member 900 may be located on an outer peripheral portion of the display area DA in a plan view, to form a closed loop. In this case, the sealing member 900 and the color conversion panel 20 may completely block the display area DA from the outside. The sealing member 900 may be a sealant or a frit. As used herein, the “plan view” is a view in z-axis direction, and the z-axis direction is a thickness direction of the display apparatus 1.

In an embodiment, a filler may be located between the display panel 10 and the color conversion panel 20.

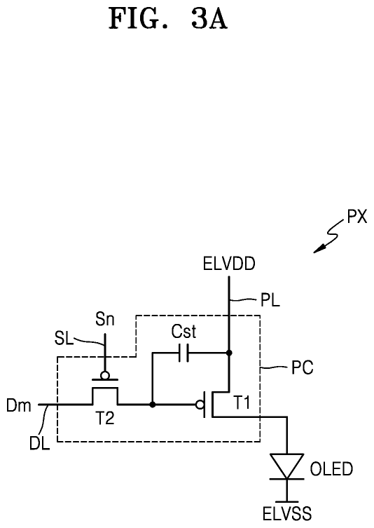

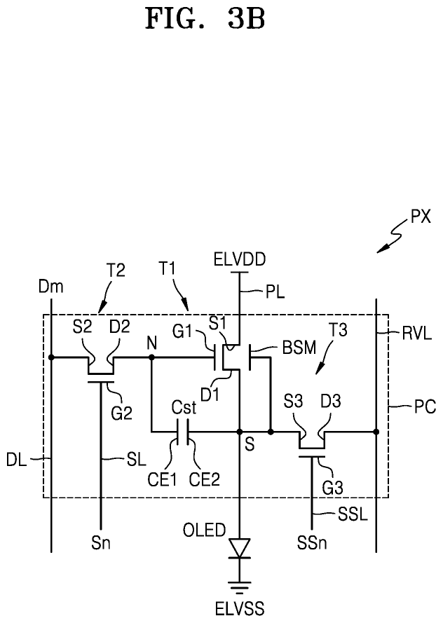

FIGS. 3A and 3B are equivalent circuit diagrams illustrating a pixel PX included in a display apparatus 1, according to embodiments.

Referring to FIG. 3A, each pixel PX may be implemented by a pixel circuit PC connected to a scan line SL and a data line DL, and an organic light-emitting diode OLED connected to the pixel circuit PC. The pixel circuit PC may include a driving thin-film transistor T1, a switching thin-film transistor T2, and a storage capacitor Cst. The switching thin-film transistor T2 may be connected to the scan line SL and the data line DL, and may transmit a data signal Dm input through the data line DL to the driving thin-film transistor T1 according to a scan signal Sn input through the scan line SL.

The storage capacitor Cst may be connected to the switching thin-film transistor T2 and a driving voltage line PL, and may store a voltage corresponding to a difference between a voltage received from the switching thin-film transistor T2 and a first power supply voltage ELVDD (or a driving voltage ELVDD) supplied to the driving voltage line PL.

The driving thin-film transistor T1 may be connected to the driving voltage line PL and the storage capacitor Cst, and may control driving current flowing through the organic light-emitting diode OLED from the driving voltage line PL in response to a value of the voltage stored in the storage capacitor Cst. The organic light-emitting diode OLED may emit light having a certain luminance due to the driving current.

Although the pixel circuit PC includes two thin-film transistors and one storage capacitor in FIG. 3A, the disclosure is not limited thereto.

Referring to FIG. 3B, the pixel circuit PC may include the driving thin-film transistor T1, the switching thin-film transistor T2, a sensing thin-film transistor T3, and the storage capacitor Cst.

The scan line SL may be connected to a gate electrode G2 of the switching thin-film transistor T2, the data line DL may be connected to a source electrode S2 of the switching thin-film transistor T2, and a first electrode CE1 of the storage capacitor Cst may be connected to a drain electrode D2 of the switching thin-film transistor T2.

Accordingly, the switching thin-film transistor T2 may supply a data signal Dm of the data line DL to a first node N in response to the scan signal Sn from the scan line SL of the corresponding pixel PX.

A gate electrode G1 of the driving thin-film transistor T1 may be connected to the first node N, a source electrode S1 of the driving thin-film transistor T1 may be connected to the driving voltage line PL for transmitting a driving voltage ELVDD, and the drain electrode D1 of the driving thin-film transistor T1 may be connected to a pixel electrode (e.g., an anode) of the organic light-emitting diode OLED.

Accordingly, the driving thin-film transistor T1 may adjust the amount of current flowing through the organic light-emitting diode OLED according to its source-gate voltage, that is, a voltage applied between the driving voltage ELVDD and the first node N.

A sensing control line SSL may be connected to a gate electrode G3 of the sensing thin-film transistor T3, a source electrode S3 of the sensing thin-film transistor T3 may be connected to a second node S, and a drain electrode D3 of the sensing thin-film transistor T3 may be connected to a reference voltage line RVL. In an embodiment, the sensing thin-film transistor T3 may be controlled by the scan line SL, instead of the sensing control line SSL.

The sensing thin-film transistor T3 may sense a potential of the pixel electrode of the organic light-emitting diode OLED. The sensing thin-film transistor T3 may supply a pre-charging voltage from the reference voltage line RVL to the second node S in response to a sensing signal SSn from the sensing control line SSL, or may supply a voltage of the pixel electrode of the organic light-emitting diode OLED to the reference voltage line RVL during a sensing period.

The storage capacitor Cst may include the first electrode CE1 connected to the first node N, and a second electrode CE2 connected to the second node S. The storage capacitor Cst may charge a difference voltage between voltages supplied to the first and second nodes N and S and may supply the difference voltage as a driving voltage of the driving thin-film transistor T1. For example, the storage capacitor Cst may charge a difference voltage between the data voltage and the pre-charging voltage supplied to the first and second nodes N and S, respectively.

A bias electrode BSM may be formed to correspond to the driving thin-film transistor T1 and may be connected to the source electrode S3 of the sensing thin-film transistor T3. Because the bias electrode BSM receives a voltage in connection with a potential of the source electrode S3 of the sensing thin-film transistor T3, the driving thin-film transistor T1 may be stabilized. In an embodiment, the bias electrode BSM may not be connected to the source electrode S3 of the sensing thin-film transistor T3, and may be connected to a separate bias wiring.

A counter electrode (e.g., a cathode) of the organic light-emitting diode OLED may receive a common voltage ELVSS. The organic light-emitting diode OLED may receive driving current from the driving thin-film transistor T1 and may emit light.

Although each pixel PX includes the scan line SL, the sensing control line SSL, the data line DL, the reference voltage line RVL, and the driving voltage line PL in FIG. 3B, the disclosure is not limited thereto. For example, at least one of the scan line SL, the sensing control line SSL, and the data line DL, and/or the reference voltage line RVL, and the driving voltage line PL may be shared by neighboring pixels in another embodiment.

The pixel circuit PC is not limited to the number of thin-film transistors and storage capacitors and a circuit design described with reference to FIGS. 3A and 3B, and the number and the circuit design may be modified in various ways.

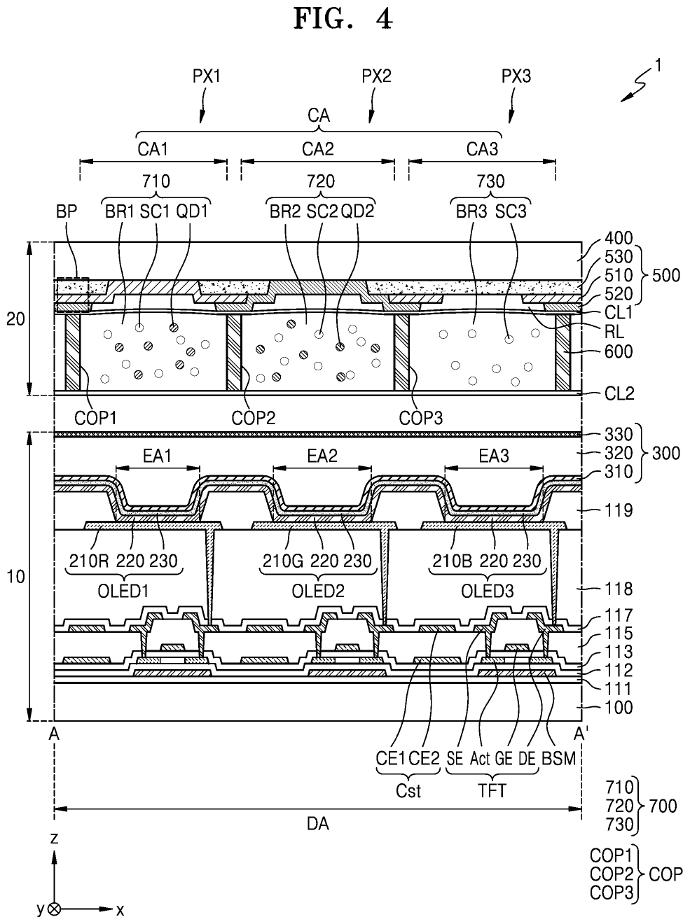

FIG. 4 is a cross-sectional view taken along line A-A′ of the display apparatus 1 shown in FIG. 1.

Referring to FIG. 4, the display apparatus 1 may include the first pixel PX1, the second pixel PX2, and the third pixel PX3 located in the display area DA. However, this is merely an example, and the display apparatus 1 may include more pixels. Although the first pixel PX1, the second pixel PX2, and the third pixel PX3 are adjacent to one another in FIG. 4, in another embodiment, the first pixel PX1, the second pixel PX2, and the third pixel PX3 may not be adjacent to one another.

The first pixel PX1, the second pixel PX2, and the third pixel PX3 may emit different light. For example, the first pixel PX1 may emit red light, the second pixel PX2 may emit green light, and the third pixel PX3 may emit blue light.

In an embodiment, the display apparatus 1 may include the display panel 10 and the color conversion panel 20. The display panel 10 may include the first substrate 100 and a display element located on the first substrate 100. The display element may include an emission layer 220. In an embodiment, the display panel 10 may include a first organic light-emitting diode OLED1, a second organic light-emitting diode OLED2, and a third organic light-emitting diode OLED3 located on the first substrate 100. The first organic light-emitting diode OLED1, the second organic light-emitting diode OLED2, and the third organic light-emitting diode OLED3 may include the emission layer 220.

Hereinafter, a stacked structure of the display panel 10 will be described in detail.

The first substrate 100 may include a glass material, a ceramic material, a metal material, or a flexible or bendable material. When the first substrate 100 is flexible or bendable, the first substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The first substrate 100 may have a single or multi-layer structure including the above material, and when the first substrate 100 has a multi-layer structure, the first substrate 100 may further include an inorganic layer. In an embodiment, the first substrate 100 may have a structure including an organic material, an inorganic material, and an organic material.

A barrier layer (not shown) may be further provided between the first substrate 100 and a first buffer layer 111. The barrier layer may prevent or minimize impurities from the first substrate 100, etc. from penetrating into a semiconductor layer Act. The barrier layer may include an inorganic material such as oxide or nitride, an organic material, or a combination of an organic material and an inorganic material, and may have a single or multi-layer structure including an inorganic material and an organic material.

The bias electrode BSM may be located on the first buffer layer 111 to correspond to a thin-film transistor TFT. In an embodiment, a voltage may be applied to the bias electrode BSM. Also, the bias electrode BSM may prevent external light from reaching the semiconductor layer Act. Accordingly, characteristics of the thin-film transistor TFT may be stabilized. The bias electrode BSM may be omitted.

The semiconductor layer Act may be located on a second buffer layer 112. The semiconductor layer Act may include amorphous silicon or polysilicon. In another embodiment, the semiconductor layer Act may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). In some embodiments, the semiconductor layer Act may be formed of a Zn oxide-based material such as Zn oxide, In—Zn oxide, or Ga—In—Zn oxide. In another embodiment, the semiconductor layer Act may be formed of an In-Ga—Zn-O (“IGZO”), In—Sn—Zn—O (“ITZO”), or In—Ga—Sn—Zn—O (“IGTZO”) semiconductor containing a metal such as indium (In), gallium (Ga), or tin (Sn) in ZnO. The semiconductor layer Act may include a channel region, and a source region and a drain region located on opposite sides of the channel region. The semiconductor layer Act may have a single or multi-layer structure.

A gate electrode GE may be located on the semiconductor layer Act with a gate insulating layer 113 therebetween. The gate electrode GE may at least partially overlap the semiconductor layer Act in a plan view. The gate electrode GE may include molybdenum (Mo), aluminum (AI), copper (Cu), or titanium (Ti), and may have a single or multi-layer structure. For example, the gate electrode GE may have a single-layer structure including Mo. The first electrode CE1 of a storage capacitor Cst may be located in the same layer as the gate electrode GE. The first electrode CE1 and the gate electrode GE may be formed of the same material.

Although the gate electrode GE of the thin-film transistor TFT and the first electrode CE1 of the storage capacitor Cst are separately located in FIG. 4, the storage capacitor Cst may overlap the thin-film transistor TFT. In this case, the gate electrode GE of the thin-film transistor TFT may function as the first electrode CE1 of the storage capacitor Cst.

An interlayer-insulating layer 115 may be provided to cover the gate electrode GE and the first electrode CE1 of the storage capacitor Cst. The interlayer-insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second electrode CE2 of the storage capacitor Cst, a source electrode SE, and a drain electrode DE may be located on the interlayer-insulating layer 115.

Each of the second electrode CE2 of the storage capacitor Cst, the source electrode SE, and the drain electrode DE may include a conductive material including molybdenum (Mo), aluminum (AI), copper (Cu), or titanium (Ti), and may have a single or multi-layer structure including the above material. For example, each of the second electrode CE2, the source electrode SE, and the drain electrode DE may have a multi-layer structure including Ti/Al/Ti. The source electrode SE and the drain electrode DE may be connected to a source region and a drain region of the semiconductor layer Act through contact holes.

The second electrode CE2 and the first electrode CE1 of the storage capacitor Cst may overlap each other with the interlayer-insulating layer 115 therebetween, to form the storage capacitor Cst. In this case, the interlayer-insulating layer 115 may function as a dielectric layer of the storage capacitor Cst.

A wiring protective layer 117 may be located on the second electrode CE2 of the storage capacitor Cst, the source electrode SE, and the drain electrode DE. In this case, the wiring protective layer 117 may include an inorganic insulating material such as silicon nitride, silicon oxide, and/or silicon oxynitride. The wiring protective layer 117 may prevent a wiring including a metal (e.g., copper) that may be damaged by an etchant in a manufacturing process of the display apparatus 1 from being exposed to an etching environment.

A planarization layer 118 may be located on the wiring protective layer 117. The planarization layer 118 may have a single or multi-layer structure formed of an organic material, and may have a flat top surface. The planarization layer 118 may include benzocyclobutene (“BCB”), polyimide, hexamethyldisiloxane (“HMDSO”), a general-purpose polymer such as polymethyl methacrylate (“PMMA”) or polystyrene (“PS”), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A display element may be located on the planarization layer 118. In an embodiment, the first organic light-emitting diode OLED1, the second organic light-emitting diode OLED2, and the third organic light-emitting diode OLED3 may be located on the planarization layer 118. The first organic light-emitting diode OLED1, the second organic light-emitting diode OLED2, and the third organic light-emitting diode OLED3 may include a first pixel electrode 210R, a second pixel electrode 210G, and a third pixel electrode 210B, respectively. In an embodiment, the first organic light-emitting diode OLED1, the second organic light-emitting diode OLED2, and the third organic light-emitting diode OLED3 may commonly include the emission layer 220 and a counter electrode 230.

Each of the first pixel electrode 210R, the second pixel electrode 210G, and the third pixel electrode 210B may be a (semi)light-transmitting electrode or a reflective electrode. In some embodiments, each of the first pixel electrode 210R, the second pixel electrode 210G, and the third pixel electrode 210B may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer formed on the reflective layer. The transparent or semi-transparent electrode layer may include at least one selected from the group consisting of indium tin oxide (“ITO”), indium zinc oxide (IZO), zinc oxide (ZnO), indium oxide (In₂O₃), indium gallium oxide (“IGO”), and aluminum zinc oxide (“AZO”). In some embodiments, the first pixel electrode 210R, the second pixel electrode 210G, and the third pixel electrode 210B may include ITO/Ag/ITO.

A pixel-defining film 119 may be located on the planarization layer 118. The pixel-defining film 119 may define opening portions through which central portions of the first pixel electrode 210R, the second pixel electrode 210G, and the third pixel electrode 210B are exposed. The pixel-defining film 119 may cover edges of the first pixel electrode 210R, the second pixel electrode 210G, and the third pixel electrode 210B. The pixel-defining film 119 may increase a distance between edges of the first pixel electrode 210R, the second pixel electrode 210G, and the third pixel electrode 210B and the counter electrode 230 over the first pixel electrode 210R, the second pixel electrode 210G, and the third pixel electrode 210B, to prevent an arc or the like from occurring on the edges of the first pixel electrode 210R, the second pixel electrode 210G, and the third pixel electrode 210B.

The pixel-defining film 119 may be formed of at least one organic insulating material selected from the group consisting of polyimide, polyamide, an acrylic resin, benzocyclobutene, and a phenolic resin by using spin coating or the like.

The emission layer 220 of the first organic light-emitting diode OLED1, the second organic light-emitting diode OLED2, and the third organic light-emitting diode OLED3 may include an organic material including a fluorescent or phosphorescent material emitting red, green, blue, or white light. The emission layer 220 may be formed of a low molecular weight organic material or a high molecular weight organic material, and functional layers such as a hole transport layer (“HTL”), a hole injection layer (“HIL”), an electron transport layer (“ETL”), and an electron injection layer (“EIL”) may be selectively located under and over the emission layer 220. Although the emission layer 220 is integrally formed over the first pixel electrode 210R, the second pixel electrode 210G, and the third pixel electrode 210B in FIG. 4, the disclosure is not limited thereto, and various modifications may be made. For example, the emission layer 220 may be located to correspond to each of the first pixel electrode 210R, the second pixel electrode 210G, and the third pixel electrode 210B in another embodiment. Here, the emission layer 220 may include a plurality of portions separated from each other and corresponding to the first pixel electrode 210R, the second pixel electrode 210G and the third pixel electrode 210B, respectively.

Although the emission layer 220 may include a layer that is integrated over the first pixel electrode 210R, the second pixel electrode 210G, and the third pixel electrode 210B as described above, the emission layer 220 may include a layer that is patterned to correspond to each of the first pixel electrode 210R, the second pixel electrode 210G, and the third pixel electrode 210B (i.e., the emission layer 220 may include a layer that is patterned to a plurality of portions which correspond to the first pixel electrode 210R, the second pixel electrode 210G, and the third pixel electrode 210B respectively) in another embodiment. In an embodiment, the emission layer 220 may be a first color emission layer. The first color emission layer may be integrated over the first pixel electrode 210R, the second pixel electrode 210G, and the third pixel electrode 210B, or may be patterned to correspond to each of the first pixel electrode 210R, the second pixel electrode 210G, and the third pixel electrode 210B (i.e., may be patterned to a plurality of portions which correspond to the first pixel electrode 210R, the second pixel electrode 210G, and the third pixel electrode 210B respectively). The first color emission layer may emit light of a first wavelength band, for example light having a wavelength ranging from 450 nm to 495 nm.

The counter electrode 230 may be located on the emission layer 220 to correspond to the first pixel electrode 210R, the second pixel electrode 210G, and the third pixel electrode 210B. The counter electrode 230 may be integrally formed in a plurality of organic light-emitting devices (e.g., a plurality of organic light-emitting diodes). In some embodiments, the counter electrode 230 may be a transparent or semi-transparent electrode, and may include a metal thin film having a low work function including lithium (Li), calcium (Ca), LiF, aluminum (AI), silver (Ag), magnesium (Mg), or a compound thereof, or a material with multilayer structure such as LiF/Ca or LiF/Al. Also, a transparent conductive oxide (“TCO”) film including ITO, IZO, ZnO, or In₂O₃ may be further located on the metal thin film.

In an embodiment, first light may be generated in a first emission area EA1 of the first organic light-emitting diode OLED1 and may be emitted to the outside. The first emission area EA1 may be defined as a portion of the first pixel electrode 210R that is exposed by an opening portion of the pixel-defining film 119. Second light may be generated in a second emission area EA2 of the second organic light-emitting diode OLED2 and may be emitted to the outside. The second emission area EA2 may be defined as a portion of the second pixel electrode 210G that is exposed by an opening portion of the pixel-defining film 119. Third light may be generated in a third emission area EA3 of the third organic light-emitting diode OLED3 and may be emitted to the outside. The third emission area EA3 may be defined as a portion of the third pixel electrode 210B that is exposed by an opening portion of the pixel-defining film 119.

The first emission area EA1, the second emission area EA2, and the third emission area EA3 may be spaced apart from one another. A portion of the display area DA other than the first emission area EA1, the second emission area EA2, and the third emission area EA3 may be a non-emission area. The first emission area EA1, the second emission area EA2, and the third emission area EA3 may be divided by the non-emission area. In a plan view, the first emission area EA1, the second emission area EA2, and the third emission area EA3 may be arranged in any of various shapes such as a stripe shape or a pentile shape. In a plan view, each of the first emission area EA1, the second emission area EA2, and the third emission area EA3 may have any one of a polygonal shape, a circular shape, and an elliptical shape.

A spacer for preventing mask damage may be further provided on the pixel-defining film 119. The spacer may be integrally formed with the pixel-defining film 119. For example, the spacer and the pixel-defining film 119 may be simultaneously formed in the same process by using a halftone mask process.

Because the first organic light-emitting diode OLED1, the second organic light-emitting diode OLED2, and the third organic light-emitting diode OLED3 may be easily damaged by external moisture or oxygen, the first organic light-emitting diode OLED1, the second organic light-emitting diode OLED2, and the third organic light-emitting diode OLED3 may be covered and protected by an encapsulation layer 300. The encapsulation layer 300 may cover the display area DA and may extend to the outside of the display area DA. The encapsulation layer 300 may include at least one organic encapsulation layer and at least one inorganic encapsulation layer. For example, the encapsulation layer 300 may include a first inorganic encapsulation layer 310, an organic encapsulation layer 320, and a second inorganic encapsulation layer 330.

Because the first inorganic encapsulation layer 310 is formed along a lower structure, a top surface of the first inorganic encapsulation layer 310 may not be flat. The organic encapsulation layer 320 covers the first inorganic encapsulation layer 310, and unlike the first inorganic encapsulation layer 310, the organic encapsulation layer 320 may have a substantially flat top surface.

Each of the first inorganic encapsulation layer 310 and the second inorganic encapsulation layer 330 may include at least one inorganic material from among aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (SiNₓ), and silicon oxynitride (SiON). The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate.

Even when cracks occur in the encapsulation layer 300, the cracks may not be connected between the first inorganic encapsulation layer 310 and the organic encapsulation layer 320 or between the organic encapsulation layer 320 and the second inorganic encapsulation layer 330 due to the multi-layer structure. Accordingly, the formation of a path through which external moisture or oxygen penetrates into the display area DA may be prevented or minimized.

Although not shown, other layers such as a capping layer may be located between the first inorganic encapsulation layer 310 and the counter electrode 230.

The color conversion panel 20 may include the second substrate 400, a color filter layer 500, a refractive layer RL, a first capping layer CL1, a bank layer 600, a functional layer 700, and a second capping layer CL2. The second substrate 400 may be located on the first substrate 100 with the display element therebetween. The second substrate 400 may be located on the first organic light-emitting diode OLED1, the second organic light-emitting diode OLED2, and the third organic light-emitting diode OLED3.

The second substrate 400 may include a central area CA overlapping the display element in a plan view. In an embodiment, the central area CA may include a first central area CA1, a second central area CA2, and a third central area CA3. The first central area CA1 may overlap the first organic light-emitting diode OLED1 and/or the first emission area EA1. The second central area CA2 may overlap the second organic light-emitting diode OLED2 and/or the second emission area EA2. The third central area CA3 may overlap the third organic light-emitting diode OLED3 and/or the third emission area EA3.

The second substrate 400 may include glass, a metal, or a polymer resin. When the second substrate 400 is flexible or bendable, the second substrate 400 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. In an embodiment, the second substrate 400 may have a multi-layer structure including two layers each including a polymer resin, and a barrier layer located between the two layers and including an inorganic material such as silicon oxide (SiO₂), silicon nitride (SiNₓ), or silicon oxynitride (SiON).

The color filter layer 500 may be located on a bottom surface of the second substrate 400 facing the first substrate 100. The color filter layer 500 may include a first color filter 510, a second color filter 520, and a third color filter 530. The first color filter 510 may be located in the first central area CA1. The second color filter 520 may be located in the second central area CA2. The third color filter 530 may be located in the third central area CA3. Each of the first color filter 510, the second color filter 520, and the third color filter 530 may be formed of a photosensitive resin material. Each of the first color filter 510, the second color filter 520, and the third color filter 530 may include a dye representing a unique color. The first color filter 510 may pass therethrough only light having a wavelength ranging from 630 nm to 780 nm, the second color filter 520 may pass therethrough only light having a wavelength ranging from 495 nm to 570 nm, and the third color filter 530 pass therethrough only light having a wavelength ranging from 450 nm to 495 nm.

The color filter layer 500 may reduce reflection of external light of the display apparatus 1. For example, when external light reaches the first color filter 510, only light having a preset wavelength may pass through the first color filter 510 as described above and light having other wavelengths may be absorbed by the first color filter 510. Accordingly, from among external light incident on the display apparatus 1, only light having a preset wavelength may pass through the first color filter 510 and part thereof may be reflected by the counter electrode 230 and/or the first pixel electrode 210R under the first color filter 510 and may be emitted to the outside again. Because only part of external light incident on the location of the first pixel PX1 is reflected, reflection of external light may be reduced. This description may also be applied to the second color filter 520 and the third color filter 530.

The first color filter 510, the second color filter 520, and the third color filter 530 may overlap one another in a plan view. The first color filter 510, the second color filter 520, and the third color filter 530 may overlap between the central areas CA. For example, the first color filter 510, the second color filter 520, and the third color filter 530 may overlap between the first central area CA1 and the second central area CA2. In this case, the third color filter 530 may be located between the first central area CA1 and the second central area CA2. The first color filter 510 may extend from the first central area CA1 and may overlap the third color filter 530. The second color filter 520 may extend from the second central area CA2 and may overlap the third color filter 530 in a plan view.

The first color filter 510, the second color filter 520, and the third color filter 530 may overlap between the second central area CA2 and the third central area CA3 in a plan view. The first color filter 510 may be located between the second central area CA2 and the third central area CA3. The second color filter 520 may extend from the second central area CA2 and may overlap the first color filter 510. The third color filter 530 may extend from the third central area CA3 and may overlap the first color filter 510.

The first color filter 510, the second color filter 520, and the third color filter 530 may overlap between the third central area CA3 and the first central area CA1. The second color filter 520 may be located between the third central area CA3 and the first central area CA1. The third color filter 530 may extend from the third central area CA3 and may overlap the second color filter 520 in a plan view. The first color filter 510 may extend from the first central area CA1 and may overlap the second color filter 520.

As described above, the first color filter 510, the second color filter 520, and the third color filter 530 may overlap to define a light-shielding unit BP in a plan view. Accordingly, the color filter layer 500 may prevent or reduced color mixing, without a separate light-shielding member.

The refractive layer RL may be located in the central area CA. The refractive layer RL may be located in each of the first central area CA1, the second central area CA2, and the third central area CA3. The refractive layer RL may include an organic material. In an embodiment, a refractive index of the refractive layer RL may be lower than a refractive index of the first capping layer CL1. In an embodiment, a refractive index of the refractive layer RL may be lower than a refractive index of the color filter layer 500. Accordingly, the refractive layer RL may condense light.

The first capping layer CL1 may be located on the refractive layer RL and the color filter layer 500. In an embodiment, the first capping layer CL1 may be located between the color filter layer 500 and the functional layer 700. The first capping layer CL1 may protect the refractive layer RL and the color filter layer 500. The first capping layer CL1 may prevent or reduce damage to or contamination of the refractive layer RL and/or the color filter layer 500 due to penetration of impurities such as external moisture and/or air. The first capping layer CL1 may include an inorganic material.

The bank layer 600 may be located on the first capping layer CL1. The bank layer 600 may include an organic material. The bank layer 600 may include a light-shielding material to function as a light-shielding layer. The light-shielding material may include at least one of, for example, a black pigment, a black dye, black particles, and metal particles.

A plurality of opening portions may be defined in the bank layer 600. For example, a central opening portion COP may be defined in the bank layer 600. The central opening portion COP may overlap the central area CA. In an embodiment, a plurality of central opening portions COP may overlap the central areas CA in a plan view. For example, a first central opening portion COP1 may overlap the first central area CA1 (here, the first central opening portion COP1 may overlap the first central area CA1 in a plan view). A second central opening portion COP2 may overlap the second central area CA2 (here, the second central opening portion COP2 may overlap the second central area CA2 in a plan view). A third central opening portion COP3 may overlap the third central area CA3 in a plan view.

The functional layer 700 may fill the central opening portion COP. In an embodiment, the functional layer 700 may include at least one of quantum dots and a scatterer. In an embodiment, the functional layer 700 may include a first quantum dot layer 710, a second quantum dot layer 720, and a transmissive layer 730.

The first quantum dot layer 710 may overlap the first central area CA1. The first quantum dot layer 710 may fill the first central opening portion COP1. The first quantum dot layer 710 may overlap the first emission area EA1. The first pixel PX1 may include the first organic light-emitting diode OLED1 and the first quantum dot layer 710.

The first quantum dot layer 710 may convert light of a first wavelength band generated by the emission layer 220 on the first pixel electrode 210R into light of a second wavelength band. For example, when light having a wavelength ranging from 450 nm to 495 nm is generated by the emission layer 220 on the first pixel electrode 210R, the first quantum dot layer 710 may convert the light into light having a wavelength ranging from 630 nm to 780 nm. Accordingly, in the first pixel PX1, the light having the wavelength ranging from 630 nm to 780 nm may be emitted to the outside through the second substrate 400. In an embodiment, the first quantum dot layer 710 may include first quantum dots QD1, a first scatterer SC1, and a first base resin BR1. The first quantum dots QD1 and the first scatterer SC1 may be dispersed in the first base resin BR1.

The second quantum dot layer 720 may overlap the second central area CA2 in a plan view. The second quantum dot layer 720 may fill the second central opening portion COP2. The second quantum dot layer 720 may overlap the second emission area EA2. The second pixel PX2 may include the second organic light-emitting diode OLED2 and the second quantum dot layer 720.

The second quantum dot layer 720 may convert light of the first wavelength band generated by the emission layer 220 on the second pixel electrode 210G into light of a third wavelength band. For example, when light having a wavelength ranging from 450 nm to 495 nm is generated by the emission layer 220 on the second pixel electrode 210G, the second quantum dot layer 720 may convert the light into light having a wavelength ranging from 495 nm to 570 nm. Accordingly, in the second pixel PX2, the light having the wavelength ranging from 495 nm to 570 nm may be emitted to the outside through the second substrate 400. In an embodiment, the second quantum dot layer 720 may include second quantum dots QD2, a second scatterer SC2, and a second base resin BR2. The second quantum dots QD2 and the second scatterer SC2 may be dispersed in the second base resin BR2.

The transmissive layer 730 may overlap the third central area CA3 in a plan view. The transmissive layer 730 may fill the third central opening portion COP3. The transmissive layer 730 may overlap the third emission area EA3. The third pixel PX3 may include the third organic light-emitting diode OLED3 and the transmissive layer 730.

The transmissive layer 730 may emit light generated by the emission layer 220 on the third pixel electrode 210B to the outside without wavelength conversion. For example, when light having a wavelength ranging from 450 nm to 495 nm is generated by the emission layer 220 on the third pixel electrode 210B, the transmissive layer 730 may emit the light to the outside without wavelength conversion. In an embodiment, the transmissive layer 730 may include a third scatterer SC3 and a third base resin BR3. The third scatterer SC3 may be dispersed in the third base resin BR3. In an embodiment, the transmissive layer 730 may not include quantum dots.

At least one of the first quantum dots QD1 and the second quantum dots QD2 may include a semiconductor material such as cadmium sulfide (CdS), cadmium telluride (CdTe), zinc sulfide (ZnS), or indium phosphide (InP). Quantum dots may have a size of several nanometers, and a wavelength of light after conversion may vary according to the size of the quantum dots.

In an embodiment, a core of a quantum dot may be selected from among a group II-VI compound, a group III-V compound, a group IV-VI compound, a group IV element, a group IV compound, and a combination thereof.

The group II-VI compound may be selected from among a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from among a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, GaAlNP, and a mixture thereof.

The group IV-VI compound may be selected from among a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The group IV element may be selected from the group consisting of silicon (Si), germanium (Ge), and a mixture thereof. The group IV compound may be a binary compound selected from the group consisting of SiC, SiGe, and a mixture thereof.

In this case, the binary compound, the ternary compound, or the quaternary compound may exist in particles at a uniform concentration, or may exist in the same particle divided into two states where concentration distributions are partially different. Also, the quantum dot may have a core/shell structure in which one quantum dot surrounds another quantum dot. An interface between the core and the shell may have a concentration gradient in which a concentration of an element in the shell gradually decreases toward the center.

In some embodiments, a quantum dot may have a core/shell structure including a core including a nanocrystal and a shell surrounding the core. The shell of the quantum dot may function as a protective layer for maintaining semiconductor characteristics by preventing chemical denaturation of the core and/or a charging layer for giving electrophoretic characteristics to the quantum dot. The shell may have a single or multi-layer structure. An interface between the core and the shell may have a concentration gradient in which a concentration of an element in the shell gradually decreases toward the center. Examples of the shell of the quantum dot may include an oxide of a metal or a non-metal, a semiconductor compound, and a combination thereof.

Examples of the oxide of the metal or the non-metal may include, but are not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO and a ternary compound such as MgAl₂O₄, CoFe₂O₄, NiFe₂O₄, or CoMn₂O₄.

Also, examples of the semiconductor compound may include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, and AISb.

Also, a quantum dot may have a shape that is generally used in the art but is not particularly limited thereto. More specifically, a quantum dot may be a spherical, pyramid, multi-arm, or cubic-shaped nano particle, nano-tube, nano-wire, nano-fiber, or nano-plate.

A color of light emitted from the quantum dot may be controlled according to a particle size, and thus, the quantum dot may have any of various emission colors such as blue, red, or green.

The first scatterer SC1, the second scatterer SC2, and the third scatterer SC3 may scatter light to emit more light. The first scatterer SC1, the second scatterer SC2, and the third scatterer SC3 may improve light extraction efficiency. At least one of the first scatterer SC1, the second scatterer SC2, and the third scatterer SC3 may be formed of any of a metal and a metal oxide for uniformly scattering light. For example, at least one of the first scatterer SC1, the second scatterer SC2, and the third scatterer SC3 may be formed of at least one of TiO₂, ZrO₂, Al₂O₃, In₂O₃, ZnO, SnO₂, Sb₂O₃, and ITO. Also, at least one of the first scatterer SC1, the second scatterer SC2, and the third scatterer SC3 may have a refractive index of 1.5 or more. Accordingly, the light extraction efficiency of the functional layer 700 may be improved. In some embodiments, at least one of the first scatterer SC1, the second scatterer SC2, and the third scatterer SC3 may be omitted.

Each of the first base resin BR1, the second base resin BR2, and the third base resin BR3 may be a light-transmitting material. For example, at least one of the first base resin BR1, the second base resin BR2, and the third base resin BR3 may include a polymer resin such as acryl polymer, benzocyclobutene (BCB), or hexamethyldisiloxane (HMDSO).

The second capping layer CL2 may be located on the bank layer 600 and the functional layer 700. The second capping layer CL2 may protect the bank layer 600 and the functional layer 700. The second capping layer CL2 may prevent or reduce damage to or contamination of the bank layer 600 and/or the functional layer 700 due to penetration of impurities such as external moisture and/or air. The second capping layer CL2 may include an inorganic material.

In some embodiments, a spacer may be further located on the second capping layer CL2. The spacer may maintain an interval between the display panel 10 and the color conversion panel 20.

In the display apparatus 1, light of the second wavelength band may be emitted to the outside in the first pixel PX1, light of the third wavelength band may be emitted to the outside in the second pixel PX2, and light of the first wavelength band may be emitted to the outside in the third pixel PX3. That is, the display apparatus 1 may display a full-color image.

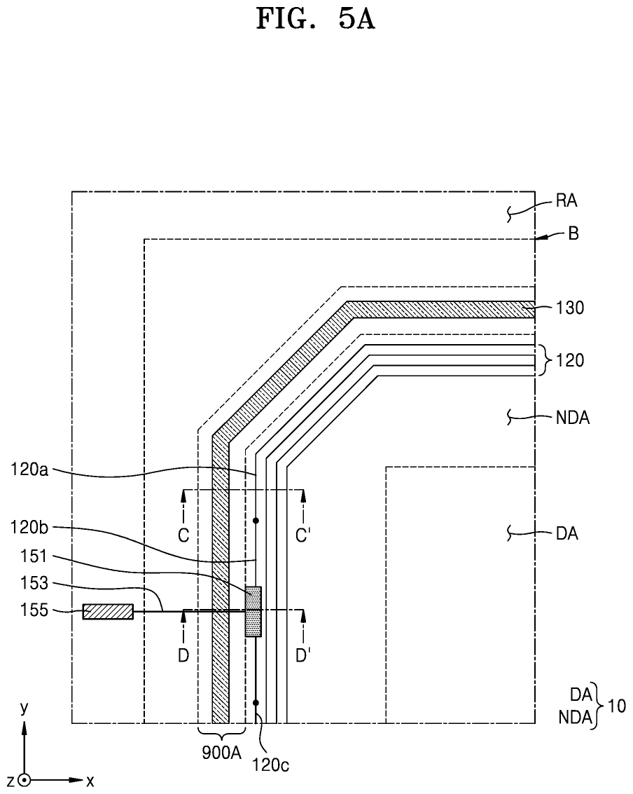

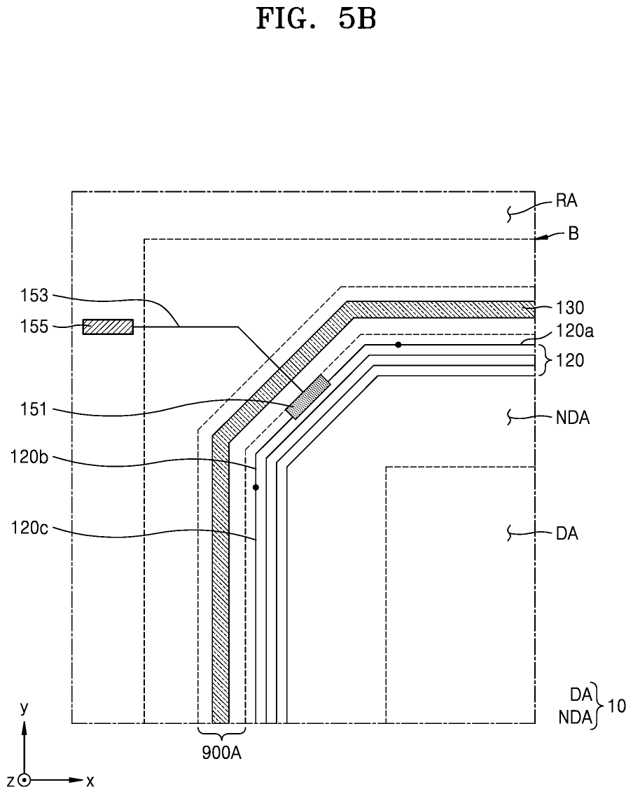

FIGS. 5A and 5B are plan views each illustrating a portion of a base substrate, according to embodiments. In FIGS. 5A and 5B, for convenience of illustration, only some of gate wirings 120, a guard ring 130, a metal pattern 151, a connection wiring 153, a monitoring pad 155, and an area 900A where the display panel 10 overlaps a sealing member 900 (e.g., see in FIG. 2) in a plan view are illustrated, and other elements are not shown. Also, in FIGS. 5A and 5B, to describe the connection wiring 153 and the monitoring pad 155, a removal area RA that is a part of a base substrate and to be separated from the display apparatus 1 (e.g., see FIG. 1) is further illustrated.

The removal area RA may be distinguished from the display panel 10 including the non-display area NDA and the display area DA by a cut line B as a boundary, and may be located on an outer peripheral portion of at least one display panel 10 formed in the base substrate.

Referring to FIGS. 5A and 5B, the display apparatus 1 may include the gate wirings 120 surrounding at least a part of the display area DA. The gate wirings 120 may be wirings for transmitting a signal to each pixel from a driving circuit unit. In an embodiment, the gate wirings 120 may include wirings for transmitting a scan signal to each pixel from the driving circuit unit.

The guard ring 130 may surround at least a part of the display area DA. In an embodiment, the guard ring 130 may be located in the area 900A overlapping the sealing member 900 to form a closed loop surrounding the display area DA. The guard ring 130 may prevent or reduce defects of the display apparatus 1 by discharging static electricity generated by the display panel 10.

The gate wirings 120 are located adjacent to the area 900A overlapping the sealing member 900 in the plan view. Accordingly, after the display panel 10 (see FIG. 2) and the color conversion panel 20 (see FIG. 2) are attached to each other, when moisture and/or impurities propagate along an interface between the sealing member 900 and the color conversion panel 20 (see FIG. 2), capacitance of the gate wiring 120 may increase. In order to monitor defects of the gate wiring 120, in an embodiment, the metal pattern 151 is located adjacent to the area 900A overlapping the sealing member 900 and at the enclosed area surrounded by the sealing member 900. In some embodiments, the metal pattern 151 may contact an inner surface of the sealing member 900. In this case, the metal pattern 151 may more easily contact moisture and/or impurities propagating along an interface between the sealing member 900 and a filler.

In an embodiment, the metal pattern 151 may overlap at least one of the gate wirings 120 in a plan view. For example, as shown in FIGS. 5A and 5B, the metal pattern 151 may partially overlap the gate wiring 120 closest to the area 900A overlapping the sealing member 900 from among the gate wirings 120 in a plan view. In another embodiment, the metal pattern 151 may overlap a plurality of gate wirings 120.

As shown in FIG. 5A, the metal pattern 151 may be arranged along an edge of the display panel 10 through which moisture and/or impurities may easily penetrate. In some embodiments, as shown in FIG. 5B, the metal pattern 151 may be located at a corner of the display panel 10. Four corners of the display panel 10 are portions that are under the greatest stress during pressurization on both the display panel 10 and the color conversion panel 20 and/or differential pressure between the display panel 10 and the color conversion panel 20 (see FIG. 2) and where moisture and/or impurities may most easily penetrate. In some embodiments, a plurality of metal patterns 151 may be located. The metal patterns 151 may be located at the edge and/or the corner of the display panel 10.

The metal pattern 151 may include a material whose electrical characteristics are changed by penetration of moisture and/or impurities. For example, the metal pattern 151 may include a material that is oxidized by moisture to increase resistance. In some embodiments, the metal pattern 151 may include silver (Ag). In some embodiments, the metal pattern 151 may have a multi-layer structure including ITO/Ag/ITO.

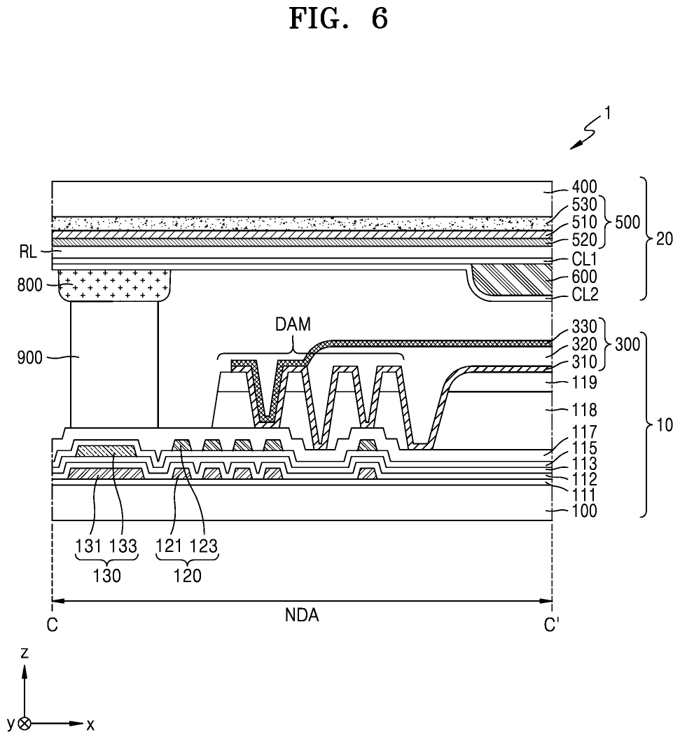

The metal pattern 151 may be electrically connected to the monitoring pad 155 located outside the area 900A overlapping the sealing member 900 (see FIG. 6) through the connection wiring 153. In this regard, in FIGS. 5A and 5B, the monitoring pad 155 is located outside the cut line B. The connection wiring 153 may extend from the metal pattern 151 to the monitoring pad 155, and cross the area 900A overlapping the sealing member 900 (see FIG. 6). A part of the connection wiring 153 and the monitoring pad 155 may be located in the removal area RA, and the remaining part of the connection wiring 153 and the metal pattern 151 may be located in the non-display area NDA. In this case, a part of the connection wiring 153 and the monitoring pad 155 may be removed when the display panel 10 is separated from the removal area RA. A part of the connection wiring 153 may remain in the display panel 10 when the display panel 10 is separated.

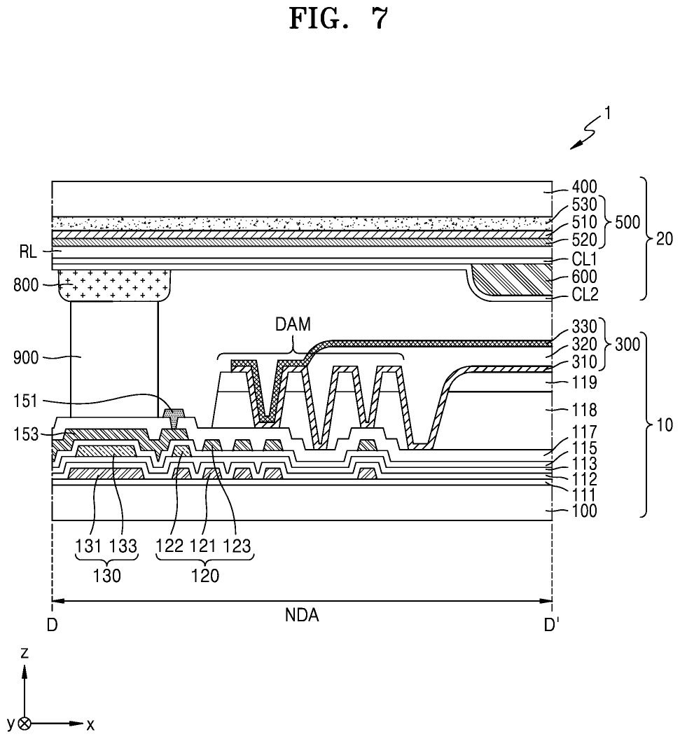

In an embodiment, the gate wiring 120 may include a first gate wiring 120a, a second gate wiring 120c, and a bridge line 120b, where the bridge line 120b is located in a portion overlapping the metal pattern 151. The first gate wiring 120a and the second gate wiring 120c may be electrically connected to each other by the bridge line 120b located therebetween. For example, when the first and second gate wirings 120a and 120c and the connection wiring 153 are located in the same layer, the bridge line 120b may be located in a different layer from the first and second gate wirings 120a and 120c and the connection wiring 153. At least one insulating layer (e.g., interlayer-insulating layer 115 in FIG. 7) may be located between the layer where the first and second gate wirings 120a and 120c are disposed and the layer where the bridge line 120b is disposed, and the bridge line 120b may be electrically connected to the first gate wiring 120a and the second gate wiring 120c through contact holes passing through the at least one insulating layer. Due to the bridge line 120b, the first gate wiring 120a may be prevented from contacting the connection wiring 153 or being interfered with the connection wiring 153, and an area for disposing the metal pattern 151 may be secured.

A method of manufacturing the display apparatus 1 (see FIG. 1) may include: forming the first substrate 100 (e.g., see FIG. 6) including the display area DA and the non-display area NDA surrounding the display area DA; forming the metal pattern 151 and the connection wiring 153 that connects the metal pattern 151 to the monitoring pad 155 on the non-display area NDA of the first substrate 100; attaching the first substrate 100 to the second substrate 400 by using the sealing member 900; and measuring a change in electrical characteristics of the metal pattern 151 by using the monitoring pad 155.

Accordingly, electrical characteristics of the metal pattern 151 may be measured by using the monitoring pad 155 while a manufacturing process is performed before the display panel 10 is separated from the removal area RA. Accordingly, a defective product may be detected and a manufacturing process may be improved by monitoring the effect of moisture and/or impurities penetrating along an interface of the sealing member 900 when the display panel 10 and the color conversion panel 20 (see FIG. 2) are attached to each other.

FIG. 6 is a cross-sectional view taken along line C-C′ of the base substrate shown in FIG. 5A. FIG. 7 is a cross-sectional view taken along line D-D′ of the base substrate shown FIG. 5A. FIGS. 6 and 7 are cross-sectional views each illustrating the display apparatus 1 including the display panel 10, the color conversion panel 20, and the sealing member 900.

Referring to FIGS. 6 and 7, the display panel 10 may include a dam portion DAM located on an edge portion of the first substrate 100. The dam portion DAM may be located outside the display area DA, and may control the flow of a monomer of the organic encapsulation layer 320 when the organic encapsulation layer 320 is formed. The dam portion DAM may include at least one dam. In an embodiment, a plurality of dam portions DAM may be located to be spaced apart from the sealing member 900.

The dam portion DAM may include an insulating layer. For example, the dam portion DAM may include the same layer as at least one of the planarization layer 118 and the pixel-defining film 119. Also, the dam portion DAM may include the wiring protective layer 117. In another embodiment, although not shown, the dam portion DAM may further include the same layer as a spacer located on the pixel-defining film 119. When the dam portion DAM includes a plurality of dams, heights of the dams may be different. For example, a height of a dam close to the sealing member 900 from among the plurality of dams may be greater than heights of the other dams.

In some embodiments, a top surface of at least one of the dams of the dam portion DAM may directly contact the first inorganic encapsulation layer 310 or the second inorganic encapsulation layer 330.

In some embodiments, a top surface of at least one of the dams of the dam portion DAM may not overlap the organic encapsulation layer 320 in a plan view. That is, the first inorganic encapsulation layer 310 and the second inorganic encapsulation layer 330 may form an inorganic contact area, to prevent or reduce penetration of moisture and impurities from an outer peripheral portion of the display panel 10 into light-emitting elements (e.g., which may refer to the display elements) located in the display area DA (see FIG. 4).

The display panel 10 may include the guard ring 130 located along the outer peripheral portion of the display panel 10. In some embodiments, the guard ring 130 may overlap the sealing member 900 in a plan view. In this case, the guard ring 130 and the sealing member 900 may have a closed loop shape surrounding the display area DA.

In some embodiments, at least one guard ring 130 may be provided. For example, the guard ring 130 may include a first guard ring 131 located between the first buffer layer 111 and the second buffer layer 112, and a second guard ring 133 located between the gate insulating layer 113 and the interlayer-insulating layer 115. The first guard ring 131 may include the same material as the bias electrode BSM (see FIG. 4) located in the display area DA (see FIG. 4). Likewise, the second guard ring 133 may include the same material as the gate electrode GE (see FIG. 4) of the thin-film transistor TFT (see FIG. 4) located in the display area DA (see FIG. 4). The first guard ring 131 and the second guard ring 133 may overlap each other in a plan view. In other embodiments, the first guard ring 131 or the second guard ring 133 may be omitted. In another embodiment, the first guard ring 131 and the second guard ring 133 may be omitted, and a dummy gate wiring (not shown) may be located in order to reduce defects due to static electricity.

The display panel 10 may include the gate wirings 120 located adjacent to the sealing member 900. The gate wirings 120 may include a lower wiring 121 located between the first buffer layer 111 and the second buffer layer 112 and an upper wiring 123 located between the interlayer-insulating layer 115 and the wiring protective layer 117. The lower wiring 121 may include the same material as the bias electrode BSM (see FIG. 4) located in the display area DA (see FIG. 4). Likewise, the upper wiring 123 may include the same material as the source electrode SE (see FIG. 4) and the drain electrode DE (see FIG. 4) located in the display area DA (see FIG. 4).

At least a part of the gate wiring 120 may overlap the dam portion DAM in a plan view, and the remaining part of the gate wiring 120 may be located between the dam portion DAM and the sealing member 900. The wiring protective layer 117 may be located on the upper wiring 123 of the gate wiring 120.

The color conversion panel 20 may include the color filter layer 500 extending to the non-display area NDA. The color filter layer 500 may include the first color filter 510, the second color filter 520, and the third color filter 530 which are stacked in the non-display area NDA. Because the first through third color filters 510, 520, and 530 are stacked to overlap one another, light of the display panel 10 may not be transmitted and thus the non-display area NDA may become a non-visible area.

The refractive layer RL may be located on the color filter layer 500 and at least one of the first capping layer CL1 and the second capping layer CL2 may be located on the refractive layer RL. That is, at least one of the first capping layer CL1 and the second capping layer CL2 may extend from a portion of the second substrate 400 corresponding to the display area DA (see FIG. 4) of the display panel 10 to an end of the second substrate 400, to shield a surface of the refractive layer RL. In this case, at least one of the first capping layer CL1 and the second capping layer CL2 may include an inorganic insulating material such as silicon oxide (SiO₂), silicon nitride (SiNₓ), and/or silicon oxynitride (SiON).

The bank layer 600 may be located between the first capping layer CL1 and the second capping layer CL2. The bank layer 600 may overlap a part of the non-display area NDA from the display area DA (see FIG. 4). In some embodiments, the bank layer 600 may define additional openings not overlapping display elements in the non-display area NDA in a plan view. The bank layer 600 may include a black matrix material, or a light-shielding material such as a red pigment, a purple pigment, or a blue pigment. Alternatively, the bank layer 600 may include a metal oxide to increase a reflectance on a surface of the bank layer 600. Accordingly, external light incident on the second substrate 400 may be effectively prevented or minimized from reaching a driving circuit unit.

An attachment portion 800 may be located between the second capping layer CL2 and the sealing member 900. The attachment portion 800 may overlap the sealing member 900 in a plan view. The attachment portion 800 may form a closed loop surrounding the display area DA (see FIG. 4). The attachment portion 800 may be formed of or include any of various materials. In an embodiment, the attachment portion 800 may include a photoresist material, an acrylic resin, an epoxy resin, polyimide, or polyethylene. In some embodiments, the attachment portion 800 may include the same material as the sealing member 900. The attachment portion 800 may reduce differential pressure between the first substrate 100 and the second substrate 400 when the display panel 10 and the color conversion panel 20 are attached. In some embodiments, the attachment portion 800 may be omitted. When the attachment portion 800 is omitted, the sealing member 900 may directly contact the second capping layer CL2.

Although not shown in FIG. 6, a filler may be located between the display panel 10 and the color conversion panel 20. For example, a filler may be filled between the second capping layer CL2 and the encapsulation layer 300. The filler may include a resin such as acryl resin or epoxy resin.

Moisture and/or impurities may penetrate along an interface between the attachment portion 800 and the sealing member 900 and an interface between the sealing member 900 and the filler. In this case, the upper wiring 123 of the gate wiring 120 located close to the sealing member 900 may be damaged by the moisture and/or impurities. Such damage to the upper wiring 123 of the gate wiring 120 is progressive damage gradually occurring as time passes. In order to monitor such damage in a manufacturing process and detect defects, as shown in FIG. 7, the display apparatus 1 may further include the metal pattern 151 and the connection wiring 153.

The metal pattern 151 may be located adjacent to the sealing member 900. The metal pattern 151 may be located on the wiring protective layer 117. The metal pattern 151 may include a material whose electrical characteristics are changed by penetration of moisture and/or impurities. In some embodiments, the metal pattern 151 may include silver (Ag). In some embodiments, the metal pattern 151 may have a stacked structure including ITO/Ag/ITO.

In some embodiments, the metal pattern 151 may include the same material as the first pixel electrode 210R (see FIG. 4), the second pixel electrode 210G (see FIG. 4), and the third pixel electrode 210B (see FIG. 4) of the display area DA (see FIG. 4). In other words, the metal pattern 151 may be simultaneously formed by using the same process as the first through third pixel electrodes 210R, 210G, and 210B (see FIG. 4) of the display area DA (see FIG. 4).

The metal pattern 151 may overlap some of the gate wirings 120 in a plan view. In this regard, although the metal pattern 151 overlaps one of the gate wirings 120 closest to the sealing member 900 in FIG. 7, the metal pattern 151 may overlap a plurality of gate wirings 120. The metal pattern 151 may be located between the sealing member 900 and the dam portion DAM. Accordingly, the metal pattern 151 may not overlap the encapsulation layer 300 located on the dam portion DAM in a plan view.

The connection wiring 153 may be located between the wiring protective layer 117 and the interlayer-insulating layer 115. In some embodiments, the connection wiring 153 may include the same material as the upper wiring 123 of the gate wiring 120. In other words, the connection wiring 153 may be simultaneously formed by using the same process as the upper wiring 123, the source electrode SE (see FIG. 4), and the drain electrode DE (see FIG. 4).

Some of the gate wirings 120 may be connected to the bridge line 120b (see FIG. 5A) to prevent contact with the connection wiring 153 or electrical influence. For example, a portion of the gate wirings 120 overlapping the connection wiring 153 in a plan view may include an intermediate wiring 122 located on a layer between the lower wiring 121 and the upper wiring 123. In this regard, FIG. 7 illustrates that the intermediate wiring 122 is located between the gate insulating layer 113 and the interlayer-insulating layer 115. In some embodiments, the intermediate wiring 122 may include the same material as the gate electrode GE (see FIG. 4) located in the display area DA (see FIG. 4). In other words, the gate electrode GE (see FIG. 4) and the intermediate wiring 122 may be simultaneously formed by using the same process.

The connection wiring 153 may extend from the inside to the outside of the sealing member 900. As described above, the connection wiring 153 may be electrically connected to the monitoring pad 155 (see FIG. 5A) located in the removal area RA (see FIG. 5A). The removal area RA (see FIG. 5A) and the monitoring pad 155 (see FIG. 5A) may be removed when the display panel 10 is separated from the removal area RA, and a part of the connection wiring 153 may remain in the non-display area NDA of the display panel 10. That is, when the display panel 10 is separated, a part of the connection wiring 153 remaining on the first substrate 100 may extend to an edge of the first substrate 100.

The metal pattern 151 may be located on the wiring protective layer 117, and may be exposed to moisture and/or impurities propagating along an interface between the sealing member 900 and the attachment portion 800 prior to the gate wirings 120. Defects due to an increase in capacitance of the gate wirings 120 may be detected by measuring electrical characteristics of the metal pattern 151.

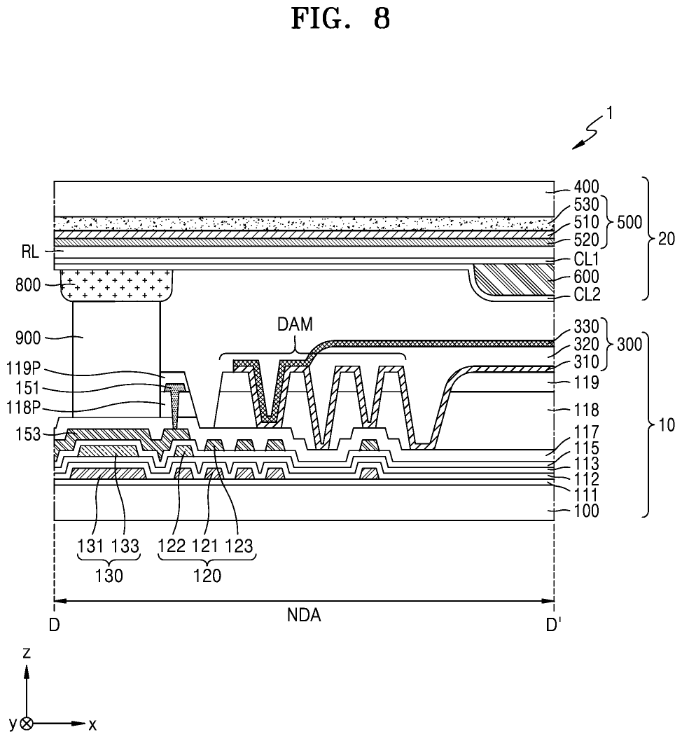

FIG. 8 is a cross-sectional view illustrating a portion of the display apparatus 1, according to an embodiment. FIG. 8 may be a cross-sectional view illustrating the display apparatus 1, taken along line D-D′ of FIG. 5A. Although FIG. 8 is similar to FIG. 7, there is a difference in that the metal pattern 151 is located between a second organic layer 118P and a first organic layer 119P.

Referring to FIG. 8, the second organic layer 118P is located adjacent to the sealing member 900 inside the sealing member 900. The second organic layer 118P may be located on the wiring protective layer 117. In an embodiment, the second organic layer 118P may include the same material as the planarization layer 118. In a plan view, the second organic layer 118P may overlap the metal pattern 151.

The first organic layer 119P may be located on the second organic layer 118P. The first organic layer 119P may be located adjacent to the sealing member 900 inside the sealing member 900, like the second organic layer 118P. In some embodiments, the first organic layer 119P may include the same material as the pixel-defining film 119. The second organic layer 118P and the first organic layer 119P may be formed by using the same process as the dam portion DAM.

The metal pattern 151 may be located between the second organic layer 118P and the first organic layer 119P, and the first organic layer 119P may cover a top surface of the metal pattern 151. The first organic layer 119P may prevent the metal pattern 151 from being oxidized in advance due to moisture exposed during a process. Also, because moisture may be absorbed by an organic layer, the second organic layer 118P and the first organic layer 119P may be located under and over the metal pattern 151 to create an environment similar to the environment of the gate wirings 120 located under the dam portion DAM.

In FIG. 8, the metal pattern 151 may be located on the second organic layer 118P, and may be connected to the connection wiring 153 through contact holes passing through the second organic layer 118P and the wiring protective layer 117. Although not shown, in some embodiments, an organic layer may be further located under and/or over the metal pattern 151. For example, the same layer as a spacer located on the pixel-defining film 119 may be further provided on the first organic layer 119P. In another embodiment, the second organic layer 118P may be omitted. For example, the metal pattern 151 may be located on the wiring protective layer 117, and only the first organic layer 119P covering the metal pattern 151 may be formed.

As described above, according to an embodiment, a display apparatus for reducing the risk of defects in a manufacturing process may be implemented. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a first substrate comprising a display area and a non-display area outside the display area;
a pixel electrode located on the display area of the first substrate;
a second substrate located over the first substrate with the pixel electrode therebetween;
a sealing member located between the first substrate and the second substrate to attach the first substrate and the second substrate to each other;
a metal pattern arranged on the first substrate to be adjacent to the sealing member at an inner side of the sealing member; and
a connection wiring connected to the metal pattern and extending to an edge of the first substrate.

2. The display apparatus of claim 1, wherein the metal pattern contacts an inner surface of the sealing member.

3. The display apparatus of claim 1, further comprising a gate wiring located on the non-display area of the first substrate,
wherein the gate wiring is located at the inner side of the sealing member in a plan view.

4. The display apparatus of claim 3, wherein the metal pattern overlaps the gate wiring in the plan view.

5. The display apparatus of claim 4, wherein the gate wiring comprises a first gate wiring and a second gate wiring, which are spaced apart from each other with the metal pattern therebetween, and a bridge line overlapping the metal pattern, in the plan view,
an insulating layer is located between a layer where the bridge line is located, and a layer where the first gate wiring and the second gate wiring are located,
and the first gate wiring and the second gate wiring are electrically connected through the bridge line.

6. The display apparatus of claim 5, wherein the connection wiring comprises a same material as a material of the first gate wiring and the second gate wiring.

7. The display apparatus of claim 5, further comprising a guard ring located on the non-display area, and arranged on the first substrate to overlap the sealing member in the plan view,
wherein the guard ring comprises a same material as a material of the bridge line.

8. The display apparatus of claim 1, further comprising a dam portion located on the non-display area of the first substrate to surround at least a part of the display area,
wherein the metal pattern is located between the sealing member and the dam portion in a plan view.

9. The display apparatus of claim 1, wherein the metal pattern comprises silver.

10. The display apparatus of claim 1, wherein the metal pattern and the pixel electrode comprise a same material.

11. The display apparatus of claim 1, wherein the metal pattern is located at a corner of the first substrate.

12. The display apparatus of claim 11, wherein the metal pattern is provided in plural so that a plurality of metal patterns are comprised, and the corner of the first substrate is provided in plural so that a plurality of corners are comprised,
wherein the plurality of metal patterns are located at the corners of the first substrate, respectively.

13. The display apparatus of claim 1, further comprising a first organic layer located at the inner side of the sealing member, and covering a top surface of the metal pattern.

14. The display apparatus of claim 13, further comprising a pixel-defining film located on the pixel electrode, and covering an edge of the pixel electrode and exposing a central portion of the pixel electrode,
wherein the first organic layer comprises a same material as a material of the pixel-defining film.

15. The display apparatus of claim 13, further comprising a second organic layer located between the metal pattern and the first substrate.

16. The display apparatus of claim 1, further comprising a color filter layer located on a bottom surface of the second substrate facing the first substrate, and comprising at least two color filters,
wherein the at least two color filters overlap each other on the non-display area in a plan view.

17. The display apparatus of claim 16, further comprising:
a refractive layer located on a bottom surface of the color filter layer facing the first substrate, and having a refractive index lower than a refractive index of the color filter layer;
a capping layer located on a bottom surface of the refractive layer facing the first substrate, and having a refractive index higher than the refractive index of the refractive layer; and
an attachment portion located between the capping layer and the sealing member.

18. The display apparatus of claim 17, wherein the attachment portion has a closed loop shape overlapping the sealing member in the plan view.

19. The display apparatus of claim 1, wherein the connection wiring is a part of a wiring, which connects the metal pattern to a monitoring pad located outside the edge of the first substrate.

20. A method of manufacturing a display apparatus, the method comprising:
forming a first substrate comprising a display area and a non-display area surrounding the display area;
forming a metal pattern on the non-display area of the first substrate, and forming a connection wiring, which electrically connects the metal pattern to a monitoring pad located outside the non-display area;
attaching a second substrate to the first substrate by using a sealing member; and
measuring a change in electrical characteristics of the metal pattern by using the monitoring pad.
